(19) United States
(12) Patent Application Publication
(10) Pub. No.: US 2026/0371697 A1
(43) Pub. Date: Nov. 19, 2026

(54) BACKSIDE SOURCE/DRAIN CONTACTS AND METHODS OF MAKING SAME

(71) Applicant: Taiwan Semiconductor Manufacturing Co., Ltd., Hsinchu (TW)

(72) Inventors: Yu-Tien Shen, Tainan City (TW); Chih-Kai Yang, Taipei City (TW); Hsin-Yuan Lee, Hsinchu (TW); Hsuan-Chin Lu, Hsinchu (TW); Hsin-Chih Wang, Zhubei City (TW); Chun-Yen Chang, Hsinchu (TW); Ming-Feng Shieh, Yongkang City (TW)

(21) Appl. No.: 19/749,830

(22) Filed: Jul. 22, 2026

Related U.S. Application Data
(63) Continuation of application No. 19/042,484, filed on Jan. 31, 2025.
(60) Provisional application No. 63/703,394, filed on Oct. 4, 2024.

(51) Int. Cl. H10D 84/01; H10D 30/00; H10D 84/83

(52) U.S. Cl. CPC H10D 84/0149; H10D 30/507; H10D 84/832

(57) ABSTRACT

A method includes forming a device layer over a substrate, the device layer comprising an upper transistor that is vertically stacked with a lower transistor; planarizing the substrate to expose a gate electrode of the lower transistor and a source/drain region of the lower transistor; and performing a directed self assembly (DSA) process to define a block of a first constituent polymer and a block of a second constituent polymer. The block of the first constituent polymer overlaps the gate electrode, and the block of the second constituent polymer overlaps the source/drain region. The method further includes replacing the block of the first constituent polymer with a dielectric material; and replacing the block of the second constituent polymer with a backside contact that is electrically connected to the source/drain region.

### PRIORITY CLAIM AND CROSS-REFERENCE

This application is a continuation of U.S. Patent Application No. 19/042,484, filed on Jan. 31, 2025, which application claims the benefit of U.S. Patent Application No. 63/703,394, filed on, Oct. 4, 2024, which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor in accordance with some embodiments.

FIGS. 2-8, 9A, 9B, 9C, 9D, 10-12, 13A, 13B, and 13C, are views of intermediate stages in the manufacturing of stacking transistors in accordance with some embodiments.

FIGS. 14-16 are views of intermediate stages in the manufacturing of stacking transistors in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure and the method of forming the same are provided. The stacking transistor may include vertically stacked transistors. Backside contacts, such as backside source/drain contacts, may be made to electrically contact lower ones of the stacking transistors. In various embodiments, the pattern of the backside contacts may be formed using a directed self-assembly (DSA) process without relying on photolithography processes. Specifically, using a surface energy difference between a gate electrode (e.g., a metal material) of the bottom transistors and an epitaxial source/drain region (e.g., a semiconductor material) of the bottom transistors, the DSA process can provide an area selective deposition process to enable self-aligned backside contacts without photolithography patterning. As a result, overlay errors resulting from wafer warpage (e.g., resulting from the formation of frontside features), bonding stress, or the like can be avoided, and backside contacts may be formed with improved reliability and fewer manufacturing errors.

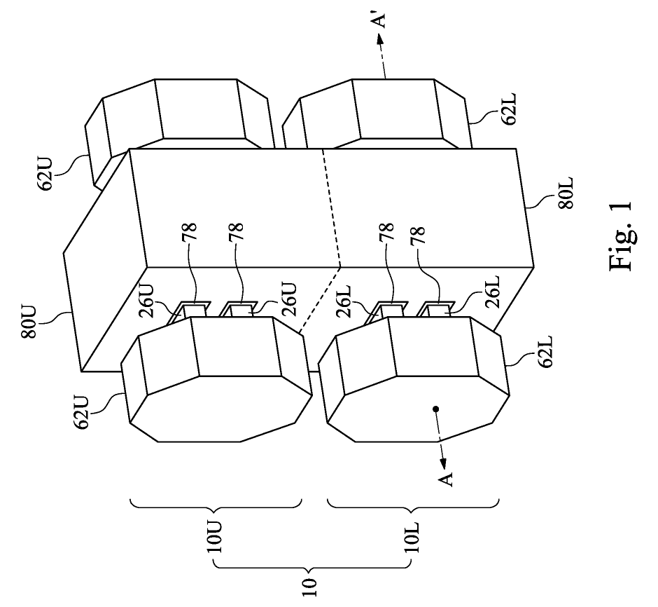

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

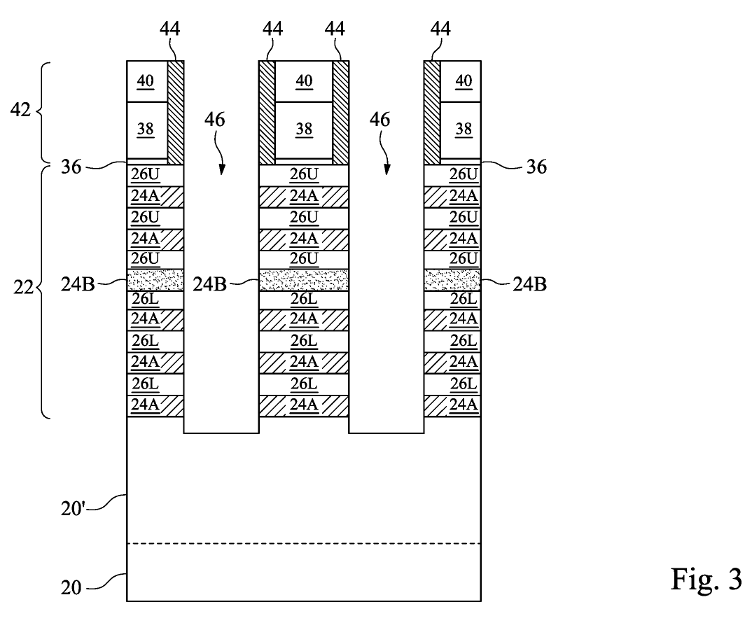

FIG. 1 further illustrates reference cross-sections that are used in later figures. Cross-section A-A' is a vertical cross-section that is parallel to a longitudinal axis of the semiconductor nanostructures 26 of a stacking transistor and in a direction of, for example, a current flow between the source/drain regions 62 of the stacking transistor. Subsequent figures(FIGS. 3 through 16) provide vertical cross-sectional views along a similar cross-section as vertical reference cross-section A-A' in FIG. 1.

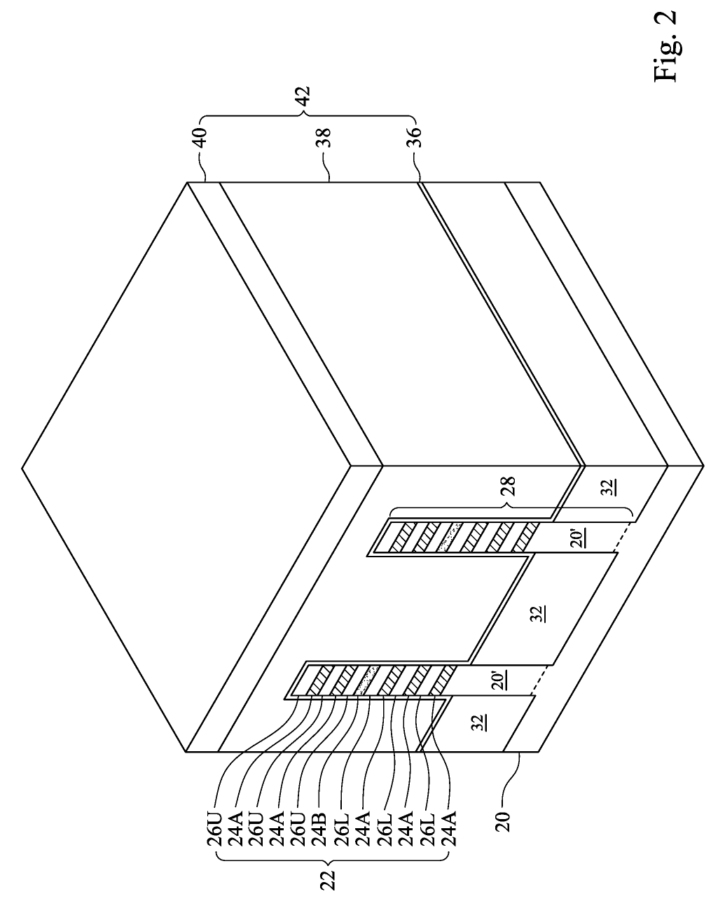

In FIG. 2, a perspective view of a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20’ (patterned portions of the semiconductor substrate 20, also referred to as semiconductor fins 20') and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. Dummy nanostructures 24A and dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent process steps without significantly removing the semiconductor nanostructures 26. In some embodiments, the dummy semiconductor nanostructures 24A are formed of or comprise silicon germanium, the semiconductor layers 26 are formed of silicon, and the dummy semiconductor nanostructures 24B may be formed of germanium or silicon germanium with a higher germanium atomic percentage than the semiconductor nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20', the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, STI regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20’. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

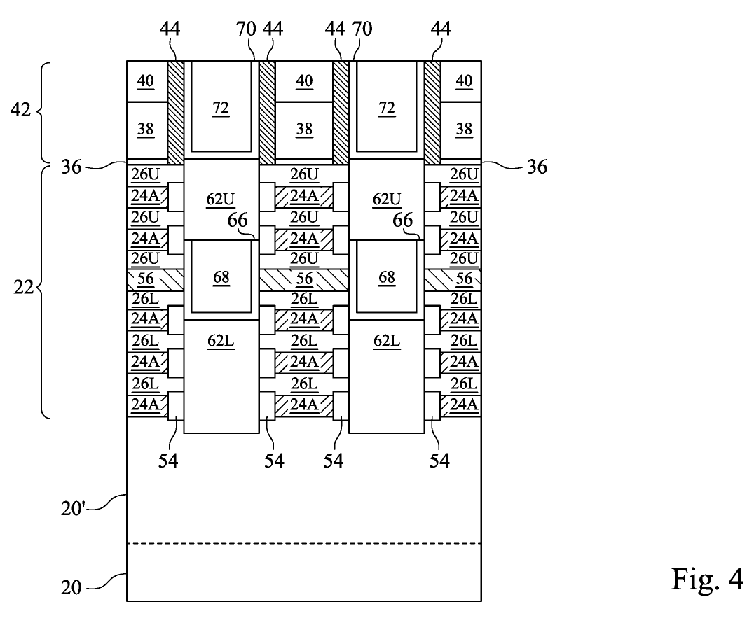

In FIG. 4, inner spacers 54 and dielectric isolation layers 56 are formed. Forming inner spacers 54 and dielectric isolation layers 56 may include an etching process that laterally etches the dummy nanostructures 24A and removes the dummy nanostructure 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A. The etching process may further slightly etch the semiconductor nanostructures 26 at a slower rate than the dummy nanostructures 24A and 24B. As a result, removing the dummy nanostructures 24B may widen a spacing between the upper semiconductor nanostructures 26U (collectively) and the lower semiconductor nanostructures 26L (collectively). Further, edge regions of the semiconductor nanostructures 26 may be thinned. In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 warp around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

Inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. Dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs. Due to the thinning of the middle semiconductor nanostructures from removing the dummy nanostructures 26B, the dielectric isolation layers 56 may be thicker than the removed, dummy nanostructures 26B.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As also illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. Inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 that are at a higher level than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the upper epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 86 (if present) or the dummy gates 84 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

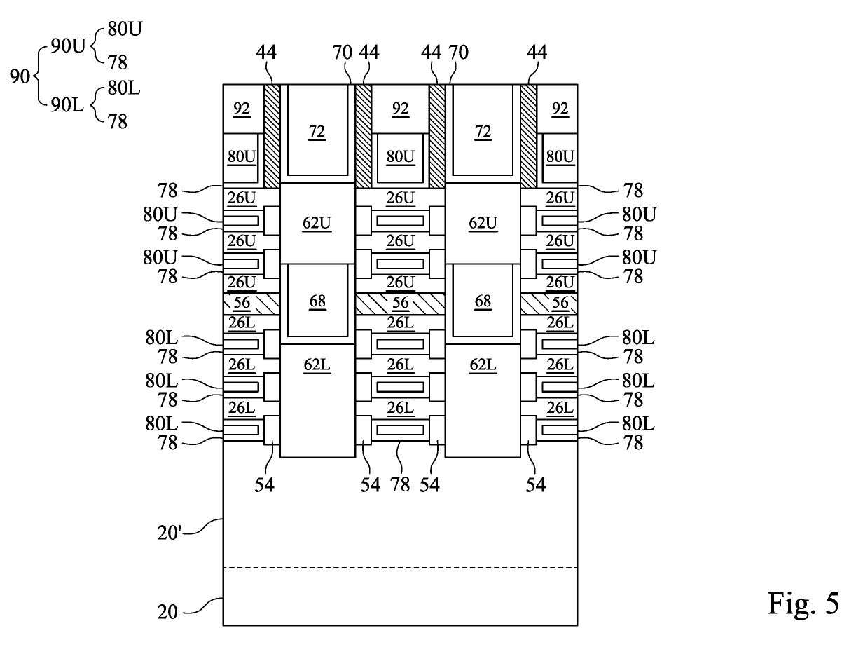

FIG. 5 illustrates a replacement gate process to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the dummy nanostructures 24A is etched at a faster rate than the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH4OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20'; on the top surfaces, the sidewalls, and the bottom surfaces of the semiconductor nanostructures 26; and on the sidewalls of the gate spacers 90. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20'.

As also shown in FIG. 5, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72.

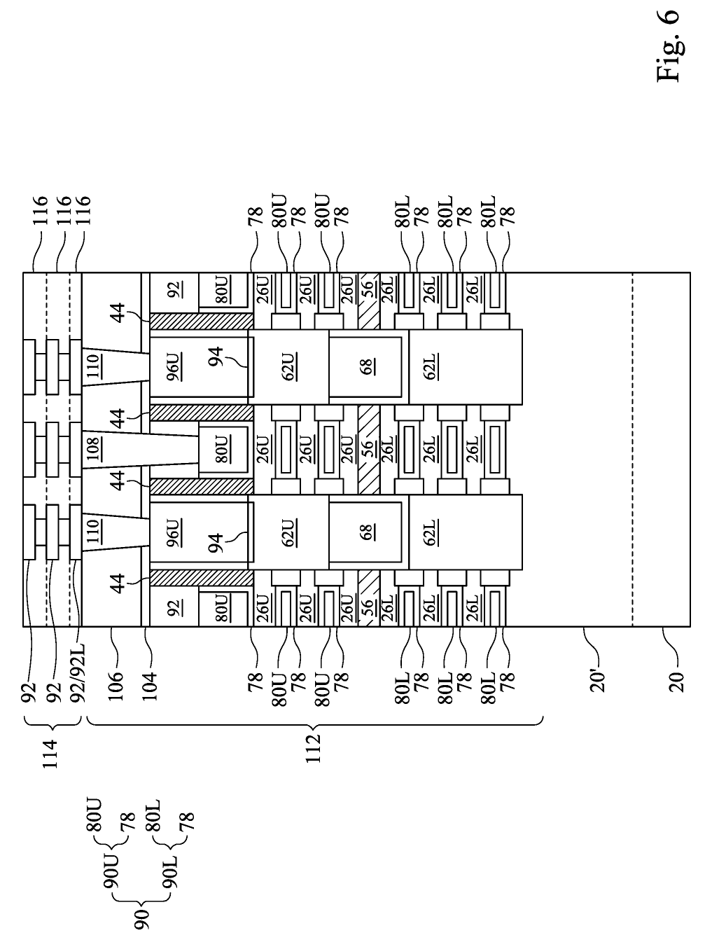

In FIG. 6, metal-semiconductor alloy regions 94 and source/drain contacts 96 are formed through the second ILD 72 to electrically couple to the upper epitaxial source/drain regions 62U and/or the lower epitaxial source/drain regions 62L. As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower source/drain regions 62L may be made through a backside of the device layer 112 (e.g., a side opposite to the front-side interconnect structure 114).

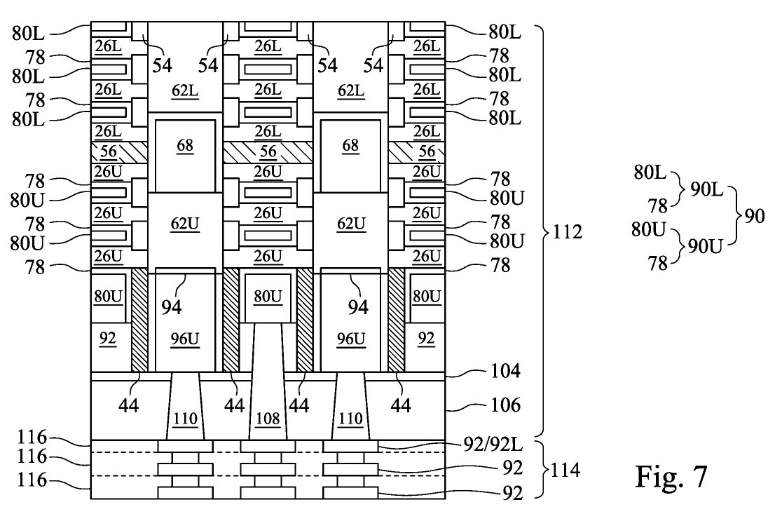

FIGS. 7 through 13C illustrate cross-sectional views of intermediate steps of forming backside contacts in accordance with some embodiments. Referring to FIG. 7, an orientation of the device may be flipped. For example, a carrier substrate (not explicitly illustrated) may be bonded to the front-side interconnect structure 114 by dielectric-to-dielectric bonding, and the device may be flipped to expose a backside of the device layer 112 (the side of the device layer 112 opposite to the front-side interconnect structure 114). Then, a planarization process may be performed on the backside of the device layer 112. In some embodiments, the planarization process may include a combination of CMP and/or etch-back processes, for example. The planarization process may remove the substrate 20 and the semiconductor strips 20' to expose the lower epitaxial source/drain regions 62L. The planarization process may further remove lateral regions of the gate dielectrics 78, such as portions between the lower gate electrodes 80L and the substrate 20 to expose a metal material of the lower gate electrodes 80L. In some embodiments, the planarization process may include thinning the lower substrate 20L with a CMP, grinding, or the like processes to remove a bulk of the lower substrate 20L. Subsequently, remaining portions of the lower substrate 20L, the semiconductor strips 20', and the lateral portions of the gate dielectric 78 may be removed by one or more CMP, etch back processes, or the like, thereby exposing the lower gate electrode 80L and the lower epitaxial source/drain regions 62L. Although not explicitly illustrated, the planarization process may also remove at least a portion of the STI regions 32 (see FIG. 2). As a result of the planarization process, the exposed, lateral surfaces of the lower gate electrode 80L and the lower epitaxial source/drain regions 62L may be substantially level (within process variations). This provides a planar base surface of the deposition of subsequent materials.

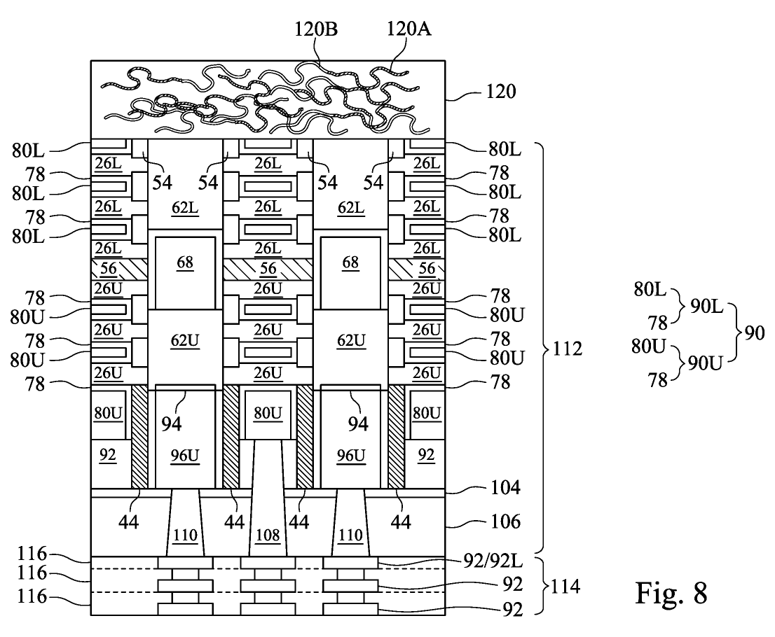

Next, in FIG. 8, a DSA material 120 is deposited over the device layer 112. The DSA material 120 allows various embodiments to exploit the property of certain substances to self-organize into regular, repeating patterns (e.g., lines) through a process known as microphase separation. The final morphology of the microphase separated layer is influenced by various factors, including the specific materials used, their relative proportions, processing conditions such as temperature, and other parameters.

In some embodiments, the DSA material 120 comprises block copolymers such as polystyrene-block-polymethyl methacrylate (PS-b-PMMA) that is in a disordered state. For example, the DSA material 120 may include PS chains 120A and PMMA chains 120B that are disordered and intermixed together. Alternatively, block copolymers of the DSA material 120 may comprise tungsten doped PS in lieu of the PS, or the like. The copolymers of the DSA material 120 may be selected so that its constituent components exhibit different sensitivities to specific etchants, and candidate materials may include any block copolymer with surface energies of two polymers being hydrophilic and hydrophobic, respectively. This property allows for selective removal of individual components in subsequent processes. In some embodiments, the DSA may be deposited by a coating process, such as spin-coating, for example. Alternatively, the DSA material 120 may be deposited by any suitable process, such as CVD, ALD, PECVD, or the like. The choice of material and deposition method depends on the specific requirements of the semiconductor device being fabricated and the desired pattern characteristics. For example, a ratio of the PS chains 120A to the PMMA chains 120B in the DSA material 120 may be in a range of 0.25 to 4. It has been observed that when the DSA material 120 is formed with a ratio of constituent copolymers in the above range, the copolymers may selectively mask features of the device layer 112 (e.g., the lower gate electrode 80L and the lower epitaxial source/drain regions 62L) in subsequent processes (e.g., after microphase separation). In some embodiments, the polymer chain length and/or weight of the copolymers in the DSA material 120 may be distributed along a curve and may not have any fixed number. For example, each polymer chain in the DSA material 120 may have a different polymer chain length and/or weight from another polymer chain in the DSA material 120.

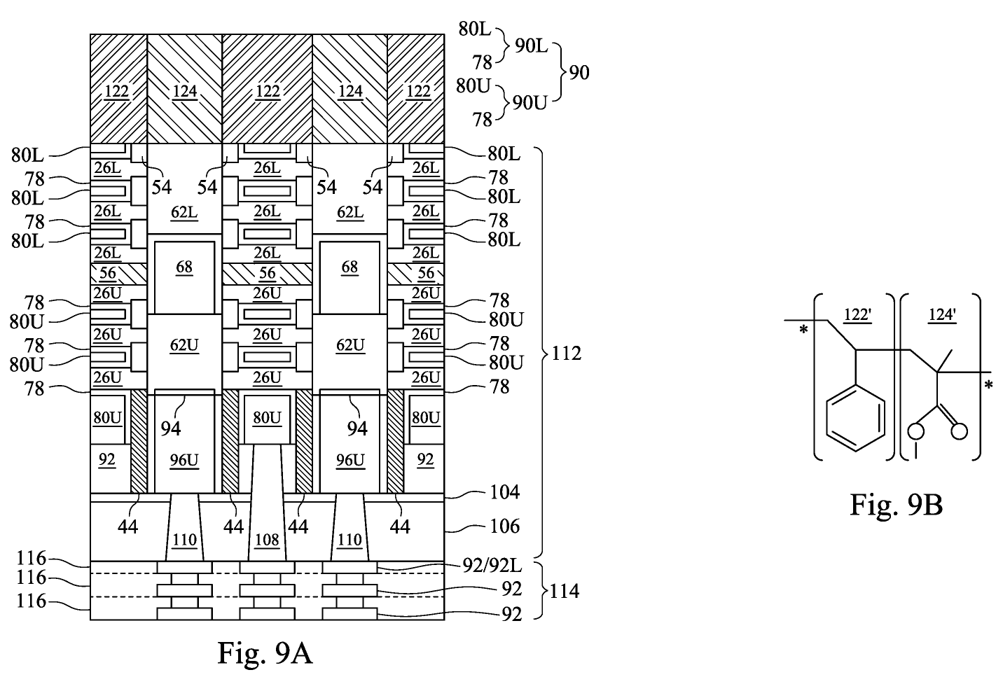

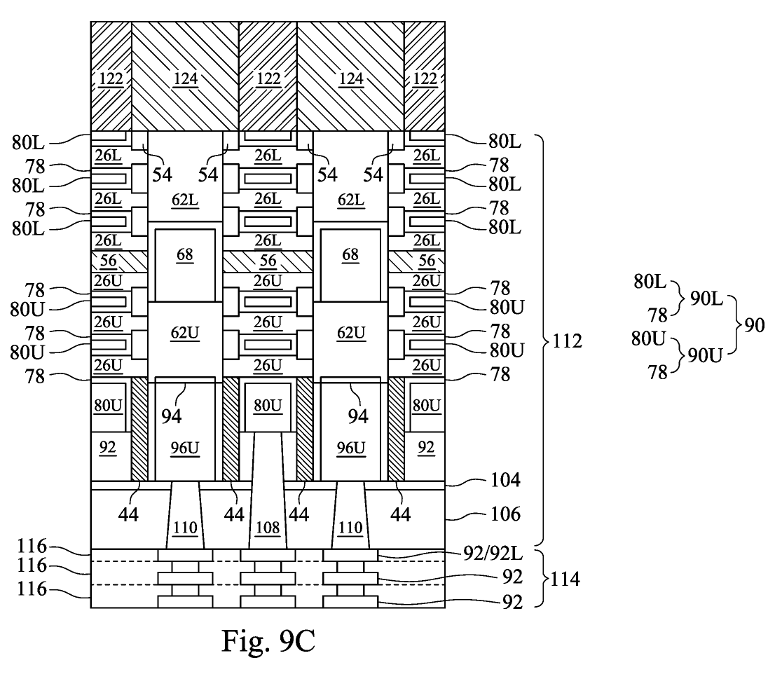

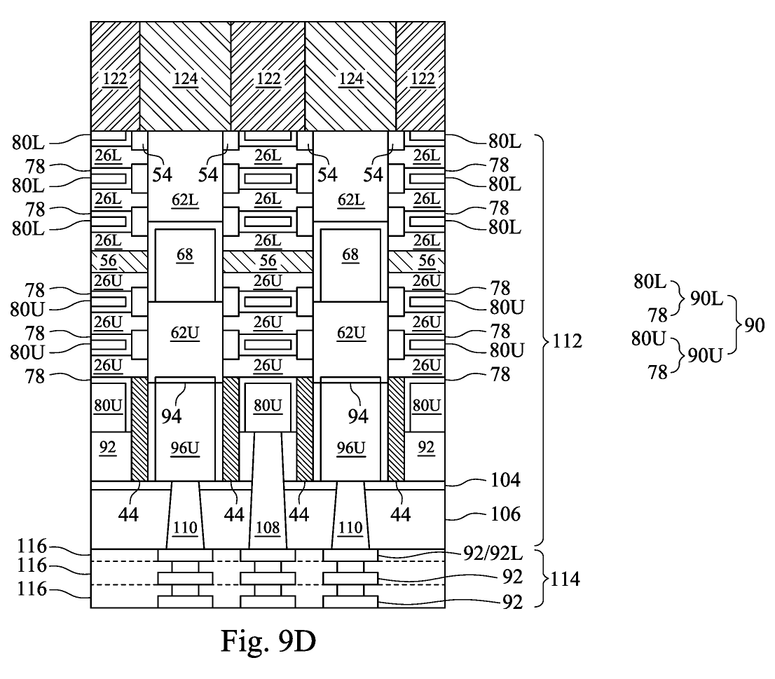

In FIGS. 9A-9D, one or more processes may be performed on the DSA material 120 to induce microphase separation. The particular processes may depend on the constituent polymers of the DSA material 120. In an exemplary embodiment, the DSA material 120 containing polystyrene and PMMA is annealed at a temperature of between about 150° C to 300° C in order to induce microphase separation. The annealing provides additional energy to facilitate PS and PMMA phase separation to meet a thermal-equilibrium state with a periodic structure where the constituent polymer blocks segregate and align to the different materials of the device layer 112.

The microphase separation forms blocks of a first constituent polymer (e.g., PS blocks 122) that are aligned with a material of the lower gate electrode 80L and blocks of a second constituent polymer (e.g., PMMA blocks 124) that are aligned with a material of the lower epitaxial source/drain regions 62L. The microphase separation is driven by the minimization of the system's free energy, including surface energy interactions between the DSA material 120 and the underlying features of the device layer 112. For example, a difference in surface energies between the materials of the lower gate electrodes 80L (e.g., a metal) and lower epitaxial source/drain regions 62L (e.g., a semiconductor material, such as silicon or silicon germanium) creates preferential wetting conditions, guiding the alignment of the constituent polymers of the DSA material 120. Specifically, the PMMA blocks 124 are aligned with the relatively hydrophilic material of the lower epitaxial source/drain regions 62L while the PS blocks 122 are aligned with the relatively hydrophobic material of the lower gate electrodes 60L. This directed self-assembly results in a periodic structure that mirrors the underlying device layout, with the final morphology dependent on the layout of the device layer 112 as well as other factors, such as the volume fraction of the PS blocks 122 and the PMMA blocks 124. FIG. 9B illustrates the structure of separated PS and PMMA blocks 122 and 124 according to some embodiments. Specifically, FIG. 9B illustrates a boundary between the PS blocks 122 and the PMMA blocks 124. Each of the PS blocks 122 may include repeating chains of the PS monomer 122' while the PMMA blocks 124 may include repeating chains of the PMMA monomer 124'.

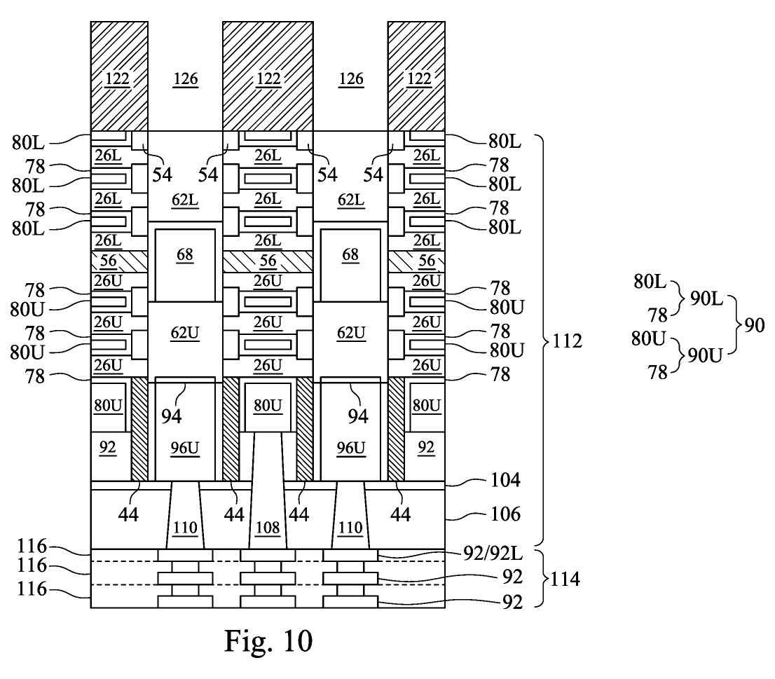

It is understood that the width of the PS blocks 122 and/or the PMMA blocks 124 not necessarily equivalent and may vary independently. Block widths may be controlled based on deposition parameters such as the selected constituent polymers, the relative concentration of constituent polymers in the DSA material coating (e.g., the DSA material 120), the use of a solvent, and/or the surface energies of other features of the device layer 112 (e.g., the inner spacers 54 and/or the gate dielectric 78). Block sizes may also be controlled during the microphase separation of the DSA material 120 via processing parameters such as temperature, or the like. By controlling these parameters, different sizes of the PS blocks 122 and/or the PMMA blocks 124 can be formed. For example, FIG. 9A illustrates embodiments where the PS blocks 122 fully overlap the inner spacers 54 and the interface between the PS blocks 122 and the PMMA blocks 124 are aligned with interfaces between the inner spacers 54 and the lower epitaxial source/drain regions 62L. As another example, FIG. 9C illustrates embodiments where the PMMA blocks 124 fully overlap the inner spacers 54 and the interface between the PS blocks 122 and the PMMA blocks 124 are aligned with interfaces between the inner spacers 54 and lower gate structures 90L. As yet another example, FIG. 9D illustrates embodiments where the PS blocks 122 and the PMMA blocks 124 each partially overlap the inner spacers 54, and the interface between the PS blocks 122 and the PMMA blocks 124 overlap lateral surfaces of the inner spacers 54. Subsequent figures(e.g., FIGS. 10-12) reference the structure of FIG. 9A for brevity, but it should be understood that various process steps may also be applied to the structures of FIGS. 9C and/or 9D .

In FIG. 10, the PMMA blocks 124 are selectively removed, defining openings 126 between the PS blocks 122 that expose the lower epitaxial source/drain regions 62L. The selective removal process does not remove the PS blocks 122. The removal process may include any suitable etching process such as an oxygen-based plasma etching process, or the like. In an exemplary embodiment, PMMA is more sensitive to oxygen-based plasma etching than PS. For example, PMMA has a higher reaction rate to oxidation than PS. Accordingly, an oxygen-based plasma etching is used to selectively remove the PMMA blocks 124 without removing the PS blocks 122. In some embodiments, the oxygen-based plasma etching process may use O₂ plasma, CO₂ plasma, or the like as an etchant.

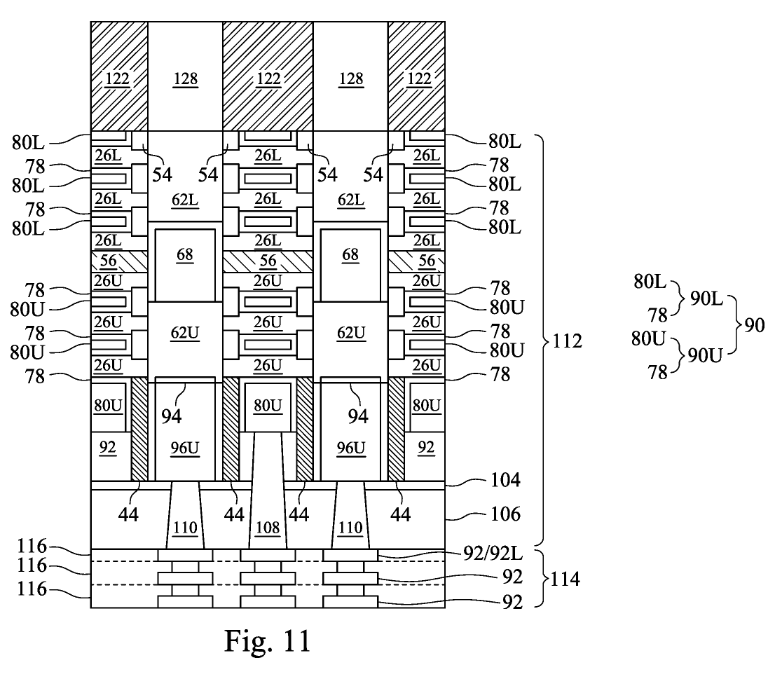

In FIG. 11, a sacrificial dielectric material 128 is deposited in the openings 126. The sacrificial dielectric material 128 may comprise a material that has etch selectivity to the material of the PS blocks 122. For example, the sacrificial dielectric material 128 may comprise an oxide, such as silicon oxide, or the like. The sacrificial dielectric material 128 may formed by any suitable process such as PVD, CVD, ALD, or the like. The sacrificial dielectric material 128 may be formed to initially overflow the openings 126 and cover the PS blocks 122. Subsequently, a removal process (e.g., a CMP, etch back process, or the like) may be performed to remove excess portions of the sacrificial dielectric material 128 and expose the PS blocks 122. Although FIG. 11 illustrates the sacrificial dielectric material 128 and the PS blocks 122 as being level, top surfaces of the PS blocks 122 may be disposed at a lower level than the sacrificial dielectric material 128 in other embodiments depending on the removal process. In subsequent processes, the sacrificial dielectric material 128 may be used to mask the lower epitaxial source/drain regions 62L during the removal of the PS blocks 122.

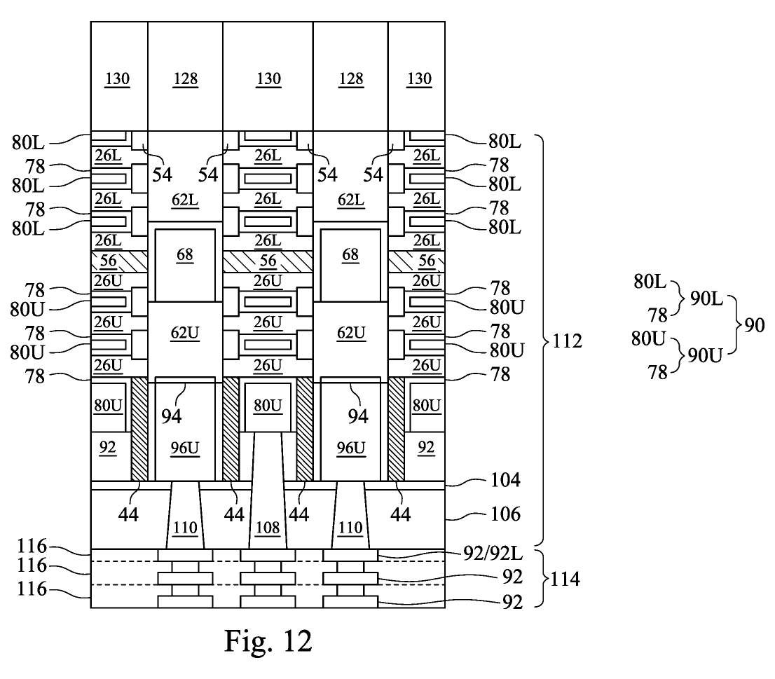

In FIG. 12, the PS blocks 122 are selectively removed and replaced with a dielectric material 130. Removing the PS blocks 122 may include an etching process that selectively etches the PS blocks 122 without significantly etching the sacrificial dielectric material 128. The etching process may be a wet etching, a dry etching, or the like with an etchant that etches the PS blocks 122 at a greater rate than the sacrificial dielectric material 128. The sacrificial dielectric material 128 masks and protects the lower epitaxial source/drain regions 62L while removing the PS blocks 122.

After the PS blocks 122 are removed, the dielectric material 130 may be deposited. The dielectric material 130 comprise a material that has etch selectivity to the material of the sacrificial dielectric material 128. For example, in embodiments where the sacrificial dielectric material 128 is made of an oxide, such as silicon oxide, or the like, the dielectric material 130 may be a nitride, such as silicon nitride, silicon oxynitride, or the like. The dielectric material 130 may formed by any suitable process such as PVD, CVD, ALD, or the like. The dielectric material 130 may be formed to initially overflow the openings formed by removing the PS blocks 122. Subsequently, a removal process (e.g., a CMP, etch back process, or the like) may be performed to remove excess portions of the dielectric material 130 and expose the sacrificial dielectric material 128.

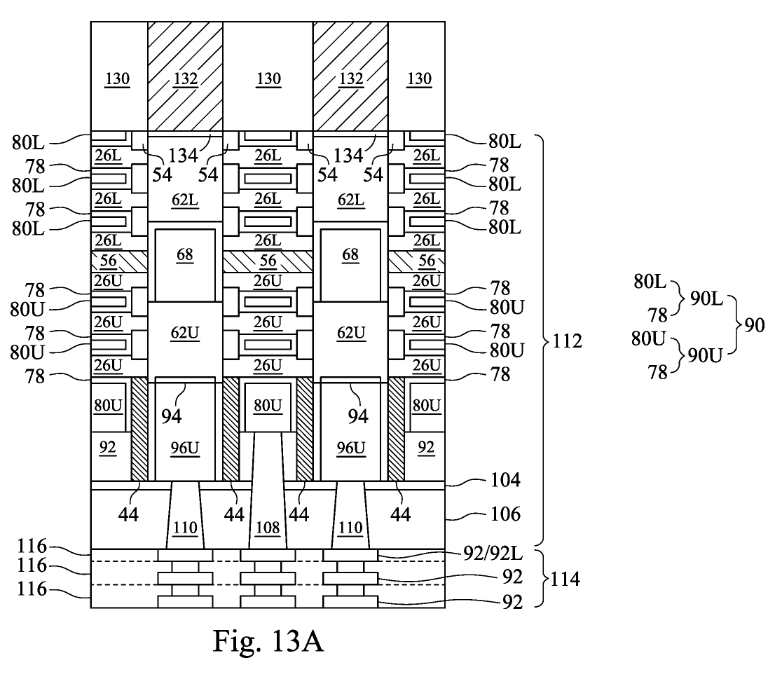

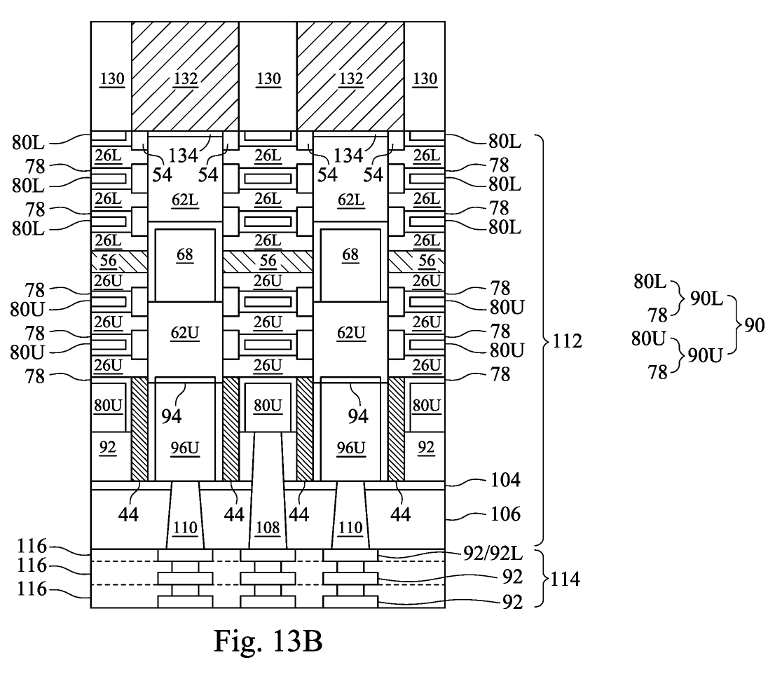

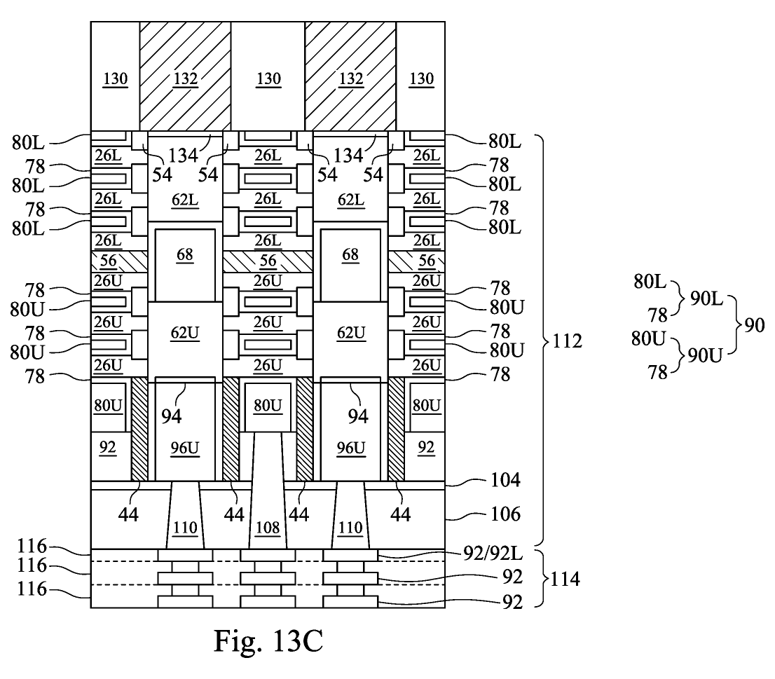

In FIGS. 13A-13C, the sacrificial dielectric material 128 is removed and replaced by backside source/drain contacts 132. The backside source/drain contacts 132 may fully overlap and cover an entire lateral surface of the lower epitaxial source/drain regions 62L in at least one cross-sectional view. Indeed, do the DSA process, the backside source/drain contacts 132 may fully cover all lateral surfaces of the lower epitaxial source/drain regions 62L that are at the backside surface of the device layer 112. Removing sacrificial dielectric material 128 may include an etching process that selectively etches the sacrificial dielectric material 128 without significantly etching the dielectric material 130. The etching process may be a wet etching, a dry etching, or the like with an etchant that etches the sacrificial dielectric material 128 at a greater rate than the dielectric material 130. Removing the sacrificial dielectric material 128 exposes the lower epitaxial source/drain regions 62L.

After the sacrificial dielectric material 128 is removed, metal-semiconductor alloy regions 134 and backside source/drain contacts 132 are formed through the dielectric material 130 to electrically couple to the lower epitaxial source/drain regions 62L. As an example to form the backside source/drain contacts 132, a liner (not separately illustrated), such as a diffusion barrier layer, an adhesion layer, or the like, and a conductive material are formed in the openings formed by removing the sacrificial dielectric material 128. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of dielectric material 130. The remaining liner and conductive material form the backside source/drain contacts 132. In some embodiments, a planarization process such as a CMP, an etch-back process, combinations thereof, or the like is utilized. After the planarization process, the top surfaces of the backside source/drain contacts 132 and the dielectric material 130 may be substantially level (within process variations).

Optionally, metal-semiconductor alloy regions 134 are formed at the interfaces between the lower source/drain regions 62L and the backside source/drain contacts 132. The metal-semiconductor alloy regions 134 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 134 can be formed before the material(s) of the lower epitaxial source/drain contacts 62L by depositing a metal in the openings for the backside source/drain contacts 132 and then performing a thermal anneal process. The metal can be any metal capable of reacting with the semiconductor materials (e.g., silicon, silicon-germanium, germanium, etc.) of the lower epitaxial source/drain regions 62L to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the backside source/drain contacts 132, such as from surfaces of the metal-semiconductor alloy regions 134. The material(s) of the backside source/drain contacts 132 can then be formed on the metal-semiconductor alloy regions 134. Additional processes, such as the formation of a backside interconnect structure (not explicitly illustrated) similar to the front-side interconnect structure 114 may also be performed.

FIG. 13A illustrates a structure resulting from performing the various processes described above on the embodiment of FIG. 9A. As a result, the backside source/drain contacts 132 includes sidewalls that are aligned with interfaces between the inner spacers 54 and the lower epitaxial source/drain regions 62L. FIG. 13B illustrates a structure resulting from performing the various processes described above on the embodiment of FIG. 9C. As a result, the backside source/drain contacts 132 fully overlap the inner spacers 54, and sidewalls of the backside source/drain contacts 132 are aligned with interfaces between the inner spacers 54 and the lower gate structure 90L. FIG. 13C illustrates a structure resulting from performing the various processes described above on the embodiment of FIG. 9D. As a result, the backside source/drain contacts 132 and the dielectric material 130 each partially overlap the inner spacers 54, and a sidewall of the backside source/drain contacts 132 overlaps lateral surfaces of the inner spacers 54.

As described above, backside contacts (e.g., backside source/drain contacts 132) are formed to the lower transistor of the device layer 112 using a DSA process that does not require any lithography processes to define a pattern of the backside contacts. Accordingly, overlay errors from the lithography processes can be avoided and manufacturing defects can be reduced. The DSA process may be particularly suited to the fine pitched features of stacking transistors with tight patterning windows. The DSA process may further alleviate any patterning challenges caused by warpage of the device layer and/or bonding stress (e.g., due to bonding a carrier substrate to the front-side interconnect structure 114, described above).

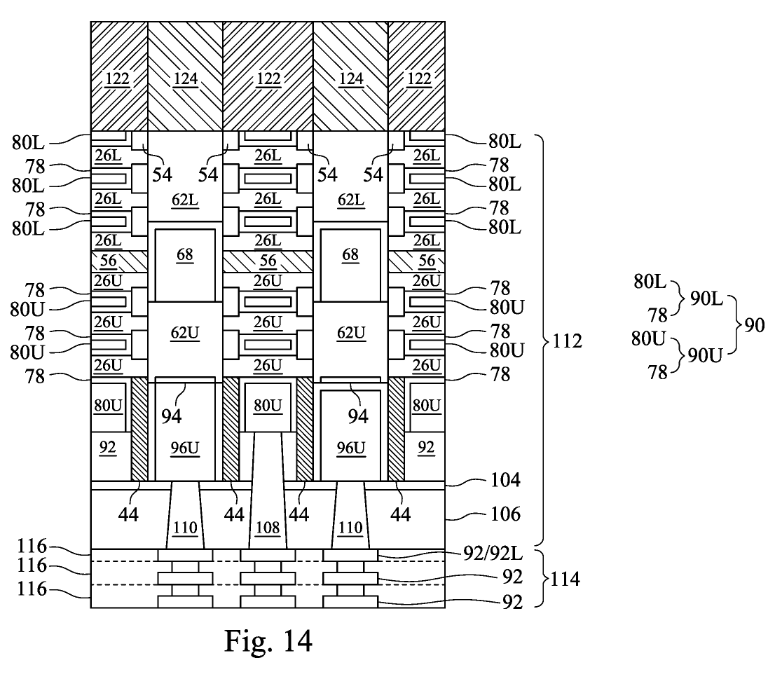

In the embodiments described above, the PMMA blocks 124 are removed prior to the PS blocks 122, and a sacrificial dielectric material 128 is used to mask the lower epitaxial source/drain regions 62L while removing the PS blocks 122. Alternatively, the sacrificial dielectric material 128 may be omitted in embodiments where the PS blocks 122 are removed prior to the PMMA blocks 124. For example FIGS. 14 through 16 illustrate embodiments where the sacrificial dielectric material 128 is omitted. In FIGS. 14 through 16, like reference numerals indicate like elements formed by like processes as those described above in FIGS. 2 through 13C unless otherwise noted.

FIG. 14 illustrates a structure at a similar phase of manufacturing as FIG. 9A were like reference numerals indicate like elements formed by like processes. For example, PS blocks 122 and PMMA blocks 124 may be formed on the device layer 112 as a result of performing a microphase separation process (e.g., annealing) on a DSA material. In some embodiments, the DSA material comprises block copolymers although other materials can be used in other embodiments. The PS blocks 122 and the PMMA blocks 124 may align with the lower gate electrodes 80L and the lower epitaxial source/drain regions 62L, respectively, due to the different surface energies of the respective materials of the lower gate electrodes 80L and the lower epitaxial source/drain regions 62L.

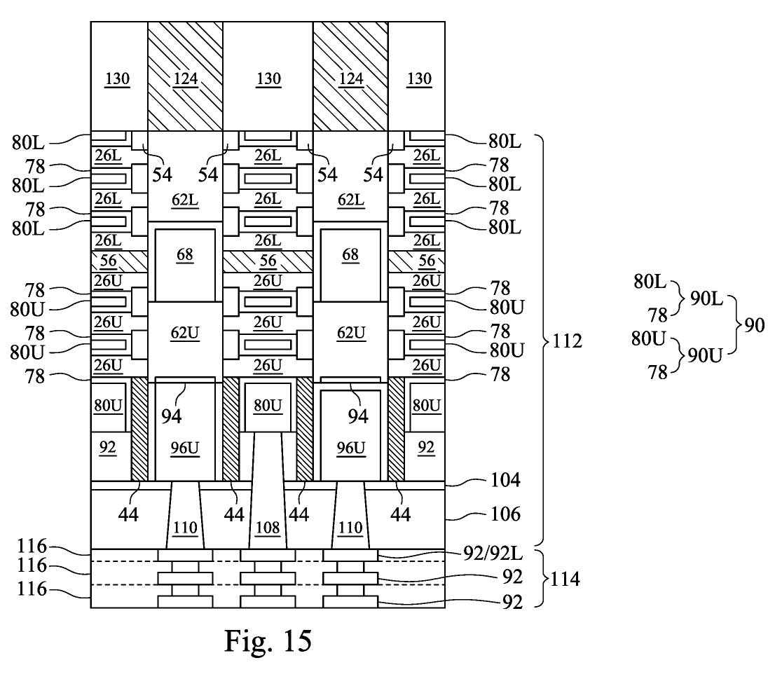

In FIG. 15, the PS blocks 122 are selectively removed and replaced with a dielectric material 130. Removing the PS blocks 122 may include a process that selectively removes the PS blocks 122 without significantly etching the PMMA blocks 124. In some embodiments, the selective removal process may include an implantation process (e.g., a sequential infiltration synthesis (SIS) process) that selectively implants a metal into the PS blocks 122 without significantly implanting the metal into the PMMA blocks 124. For example, the SIS process may include exposing the PS blocks 122 and the PMMA blocks 124 to a vapor-phase, metal-comprising precursor (e.g., trimethyl aluminum (TMA), or the like) and an oxygen-comprising precursor (e.g., H2O, H2O, O3, or the like). Due the relatively high polarity of the PS blocks 122 and the relatively low polarity of the PMMA blocks 124, the metal-comprising precursor selectively reacts with the PS blocks 122 without significantly reacting with the PMMA blocks 124 to selectively implant the metal (e.g., Al, or the like) of the metal-comprising precursor into the PS blocks 122. The oxygen-comprising precursor may also react with exposed surfaces of the PS blocks 122 to promote implantation of the metal of the metal-comprising precursor into the PS blocks 122. As a result of the SIS process, the PS blocks 122 may be implanted with metal and oxygen (e.g., AlOx) while the PMMA blocks 124 remain relatively free of metal. By selectively implanting metal into the PS blocks 122, etch selectivity between the PS blocks 122 and the PMMA blocks 124 can be achieved. Subsequently, a selective etching process (e.g., a dry etching process, a plasma etching process, or the like) may be used to selectively removed the metal-implanted PS blocks 122 withe removing the PMMA blocks 124. In some embodiments, the etching process may use any etchant (e.g., an oxygen based etchant, a fluorine based etchant, or the like) that etches the metal-implanted PS blocks 122 at a significantly faster rate than the PMMA blocks 124. The PMMA blocks 124 masks and protects the lower epitaxial source/drain regions 62L while removing the PS blocks 122, thereby removing the need to form the sacrificial dielectric material 128.

After the PS blocks 122 are removed, the dielectric material 130 may be deposited. The dielectric material 130 comprise a material that has etch selectivity to the material of the PMMA blocks 124. For example, the dielectric material 130 may be a nitride, such as silicon nitride, silicon oxynitride, or the like. The dielectric material 130 may formed by any suitable process such as PVD, CVD, ALD, or the like. The dielectric material 130 may be formed to initially overflow the openings formed by removing the PS blocks 122. Subsequently, a removal process (e.g., a CMP, etch back process, or the like) may be performed to remove excess portions of the dielectric material 130 and expose the PMMA blocks 124.

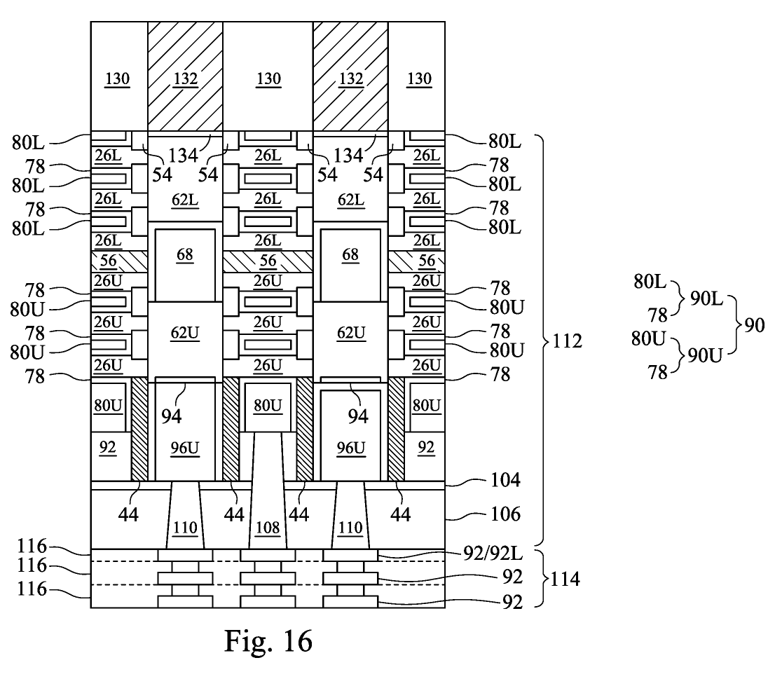

In FIG. 16, the PMMA blocks 124 is removed and replaced by backside source/drain contacts 132. Removing the PMMA blocks 124 may include an etching process that selectively etches the PMMA blocks 124 without significantly etching the dielectric material 130. The etching process may be a wet etching, a dry etching, or the like with an etchant that etches the PMMA blocks 124 at a greater rate than the dielectric material 130. Alternatively, an oxygen-based plasma etching process may be used to remove the PMMA blocks 124. Removing the PMMA blocks 124 exposes the lower epitaxial source/drain regions 62L. After the PMMA blocks 124 are removed, metal-semiconductor alloy regions 134 and backside source/drain contacts 132 are formed through the dielectric material 130 to electrically couple to the lower epitaxial source/drain regions 62L. The metal-semiconductor alloy regions 134 and the backside source/drain contacts 132 may be made of similar materials and processes as described above in FIGS. 13A through 13C. Although FIG. 16 illustrates an embodiment corresponding to FIG. 9A, it should be appreciated that the method steps of FIGS. 14-16 may be also be applied to the configures of FIGS. 9C and /or 9D .

Backside contacts, such as those for source/drain regions, can be created to electrically connect lower transistors in a stacked configuration. A DSA process, which leverages the surface energy differences between gate electrodes and epitaxial source/drain regions, can be employed to form these contacts without relying on photolithography processes. This DSA-based approach enables area-selective deposition, resulting in self-aligned backside contacts. Consequently, this method mitigates overlay errors caused by wafer warpage or bonding stress, leading to improved reliability and reduced manufacturing defects in backside contact formation.

In some embodiments, a method includes forming a device layer over a substrate, the device layer comprising an upper transistor that is vertically stacked with a lower transistor; planarizing the substrate to expose a gate electrode of the lower transistor and a source/drain region of the lower transistor; performing a directed self assembly (DSA) process to define a block of a first constituent polymer and a block of a second constituent polymer, the block of the first constituent polymer overlapping the gate electrode, and the block of the second constituent polymer overlapping the source/drain region; replacing the block of the first constituent polymer with a dielectric material; and replacing the block of the second constituent polymer with a backside contact that is electrically connected to the source/drain region. Optionally, in some embodiments, performing the DSA process comprises: depositing a DSA material over the gate electrode and the source/drain region, the DSA material comprising the first constituent polymer and the second constituent polymer in a disordered state; and performing a microphase separation process to define the block of the first constituent polymer and the block of the second constituent polymer. Optionally, in some embodiments, the DSA material comprises polystyrene-block-polymethyl methacrylate (PS-b-PMMA). Optionally, in some embodiments, the first constituent polymer is polystyrene, and wherein the second constituent polymer is polymethyl methacrylate. Optionally, in some embodiments, the microphase separation process is an annealing process. Optionally, in some embodiments, the device layer comprises an inner spacer between the source/drain region and the gate electrode, and wherein the block of the first constituent polymer overlaps the inner spacer. Optionally, in some embodiments, the device layer comprises an inner spacer between the source/drain region and the gate electrode, and wherein the block of the second constituent polymer overlaps the inner spacer. Optionally, in some embodiments, the device layer comprises an inner spacer between the source/drain region and the gate electrode, and wherein the block of the first constituent polymer and the block of the second constituent polymer each overlaps the inner spacer.

In some embodiments, a method includes forming a device layer over a substrate, the device layer comprising an upper transistor that is vertically stacked with a lower transistor; planarizing the substrate to expose a first material of the lower transistor and a second material of the lower transistor, wherein the first material and the second material have different surface energies; after planarizing the substrate, depositing a directed self assembly (DSA) material over the device layer, the DSA material comprising polystyrene-block-polymethyl methacrylate (PS-b-PMMA); performing an annealing process on the DSA material to define a polystyrene (PS) block overlapping the first material and a polymethyl methacrylate (PMMA) block overlapping the second material; and replacing the PS block with a dielectric material and the PMMA block with a conductive material. Optionally, in some embodiments, the first material is a conductive material of a gate electrode, and wherein the second material is a semiconductor material of a source/drain region. Optionally, in some embodiments, replacing the PS block with the dielectric material and the PMMA block with the conductive material comprises: removing the PMMA block to define an opening exposing the second material; depositing a sacrificial dielectric material in the opening; after depositing the sacrificial dielectric material, replacing the PS block with a dielectric material; and replacing the sacrificial dielectric material with the conductive material. Optionally, in some embodiments, removing the PMMA block comprises an oxygen-based plasma etching process. Optionally, in some embodiments, the oxygen-based plasma etching process comprises using O2 plasma or CO2 plasma as an etchant. Optionally, in some embodiments, the sacrificial dielectric material is an oxide, and the dielectric material is a nitride. Optionally, in some embodiments, replacing the PS block with the dielectric material and the PMMA block with the conductive material comprises: removing the PS block to define an opening exposing the first material; depositing the dielectric material in the opening; and after depositing the dielectric material, replacing the PMMA block with the conductive material. Optionally, in some embodiments, the first material is more hydrophobic than the second material.

In some embodiments, a device includes a first nanostructure extending to a first source/drain region; a second nanostructure extending to a second source/drain region, wherein the second nanostructure overlaps the first nanostructure, and the second source/drain region overlaps the first source/drain region; a first gate electrode around the first nanostructure; a second gate electrode around the second nanostructure, wherein the second gate electrode overlaps the first gate electrode; a dielectric material contacting the first gate electrode; and a backside contact extending through the dielectric material to the first source/drain region, wherein the backside contact covers an entire lateral surface of the first source/drain region in a cross-sectional view. Optionally, in some embodiments, the device further includes an inner spacer between first source/drain region and the first gate electrode, wherein an interface between the backside contact and the dielectric material is aligned with an interface between the inner spacer and the first source/drain region. Optionally, in some embodiments, the device further includes an inner spacer between first source/drain region and the first gate electrode, wherein an interface between the backside contact and the dielectric material overlaps a lateral surface of the inner spacer. Optionally, in some embodiments, the device further includes an inner spacer between first source/drain region and a first gate stack, wherein the first gate stack comprises the first gate electrode, and wherein an interface between the backside contact and the dielectric material is aligned with an interface between the inner spacer and the first gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first source/drain region adjoining a channel region, wherein the channel region is over a substrate;
forming a first gate structure surrounding the channel region;
at least partially removing the substrate to expose a backside of the first gate structure and a backside of the first source/drain region;
forming a block of a first constituent polymer on the backside of the first gate structure and a block of a second constituent polymer on the backside of the first source/drain region;
selectively removing the block of the first constituent polymer to define a first opening;
forming a first dielectric material in the first opening; and
replacing the block of the second constituent polymer with a backside contact that is electrically connected to the first source/drain region.

2. The method of claim 1, wherein forming the block of the first constituent polymer on the backside of the first gate structure and the block of the second constituent polymer on the backside of the first source/drain region comprises:
depositing a directed self assembly (DSA) material over the first gate structure and the first source/drain region, the DSA material comprising the first constituent polymer and the second constituent polymer in a disordered state; and
performing a microphase separation process to define the block of the first constituent polymer and the block of the second constituent polymer.

3. The method of claim 2, wherein the DSA material comprises polystyrene-block-polymethyl methacrylate (PS-b-PMMA).

4. The method of claim 3, wherein the first constituent polymer is polystyrene, and wherein the second constituent polymer is polymethyl methacrylate.

5. The method of claim 2, wherein the microphase separation process is an annealing process.

6. The method of claim 1, wherein replacing the block of the second constituent polymer with the backside contact that is electrically connected to the first source/drain region comprises:
prior to selectively removing the block of the first constituent polymer, replacing the block of the second constituent polymer with a second dielectric material; and
after forming the first dielectric material in the first opening, replacing the second dielectric material with the backside contact.

7. The method of claim 1, wherein replacing the block of the second constituent polymer with the backside contact that is electrically connected to the first source/drain region comprises:
after selectively removing the block of the first constituent polymer, replacing the block of the second constituent polymer with the backside contact.

8. The method of claim 7, wherein selectively removing the block of the first constituent polymer comprises:
selectively doping the block of the first constituent polymer with a metal element.

9. The method of claim 8, wherein selectively removing the block of the first constituent polymer further comprises:
selectively doping the block of the first constituent polymer with oxygen.

10. A method comprising:
forming a device layer over a substrate, the device layer comprising an upper transistor that is vertically stacked with a lower transistor;
planarizing the substrate to expose a first surface and a second surface of the lower transistor, wherein the second surface is more hydrophilic than the first surface;
after planarizing the substrate, depositing a directed self assembly (DSA) material over the device layer, the DSA material comprising polystyrene-block-polymethyl methacrylate (PS-b-PMMA);
performing an annealing process on the DSA material to define a polystyrene (PS) block on the first surface and a polymethyl methacrylate (PMMA) block on the second surface;
replacing the PMMA block with a sacrificial material;
replacing the PS block with an insulating material; and
replacing the sacrificial material with a conductive contact.

11. The method of claim 10, wherein the first surface is a surface of a gate electrode, and wherein the second surface is a surface of a source/drain region.

12. The method of claim 11, wherein replacing the PMMA block with the insulating material comprises:
performing an oxygen-based plasma etch to remove the PMMA block and define a first opening; and
depositing the insulating material in the first opening.

13. The method of claim 12, wherein the oxygen-based plasma etch comprises using O₂ plasma or CO₂ plasma as an etchant.

14. The method of claim 10, wherein the sacrificial material is an oxide, and the insulating material is a nitride.

15. The method of claim 10, wherein the annealing process is performed at a temperature in a range of 150° C to 300° C.

16. The method of claim 10, wherein a ratio of PS chains to PMMA chains in the DSA material is in a range of 0.25 to 4.

17. A device comprising:
a first nanostructure adjoining a first source/drain region;
a second nanostructure adjoining a second source/drain region, wherein the second nanostructure overlaps the first nanostructure, and the second source/drain region overlaps the first source/drain region;
a first gate electrode around the first nanostructure in a first cross-sectional view;
an inner spacer between the first gate electrode and the first source/drain region in a second cross-sectional view perpendicular to the first cross-sectional view;
a second gate electrode around the second nanostructure, wherein the second gate electrode overlaps the first gate electrode;
a dielectric material interfacing a backside surface of the first gate electrode in the second cross-sectional view; and
a backside contact extending through the dielectric material to a backside surface of the first source/drain region, wherein the backside contact spans an entire width of the backside surface of the first source/drain region in the second cross-sectional view.

18. The device of claim 17, wherein an interface between the backside contact and the dielectric material is aligned with an interface between the inner spacer and the first source/drain region.

19. The device of claim 17, wherein an interface between the backside contact and the dielectric material overlaps a lateral surface of the inner spacer.

20. The device of claim 17, wherein an interface between the backside contact and the dielectric material is aligned with a sidewall of the inner spacer that faces the first gate electrode.
